(19) United States
(12) Patent Application Publication
(10) Pub. No.: US 2017/0018397 A1
(43) Pub. Date: Jan. 19, 2017

(54) SAMPLE HOLDER FOR CHARGED PARTICLE BEAM DEVICE, AND CHARGED PARTICLE BEAM DEVICE

(71) Applicant: HITACHI HIGH-TECHNOLOGIES CORPORATION, Tokyo (JP)

(72) Inventors: Yuya SUZUKI, Tokyo (JP); Isao NAGAOKI, Tokyo (JP); Hiroaki MATSUMOTO, Tokyo (JP)

(21) Appl. No.: 15/124,684

(22) PCT Filed: Mar. 28, 2014
(86) PCT No.: PCT/JP2014/059066

§ 371 Date: Sep. 9, 2016

(51) Int. Cl. H01J 37/20; G01N 23/225; H01J 37/26; H01J 37/244

(52) U.S. Cl. CPC H01J 37/20; H01J 37/244; G01N 23/2252; H01J 37/26; H01J 2237/2445; H01J 2237/2561

(57) ABSTRACT

In energy dispersive X-ray (EDX) analysis, an increase in the area of a detector causes a decrease in the peak/background ratio of a detected signal. In order to solve this problem, a sample holder has a main body part for holding a sample, and a sample retaining part detachably provided to the main body part; the sample retaining part being mounted on the main body part to secure the sample held by the main body part, and the sample retaining part having: a first hole for allowing a charged particle beam to pass therethrough; and a second hole for introducing, from among signals generated by the sample, only a specific signal into a detector. The sample holder is applicable to a charged particle beam device, for example.

### TECHNICAL FIELD

The present invention relates to a sample holder for a charged particle beam device, and a charged particle beam device, and particularly to a sample holder which contributes a high accuracy in analysis using a characteristic X ray, and a device to which the sample holder is applied.

### BACKGROUND ART

As one of methods of analyzing composition of a sample using a charged particle beam device such as an electron microscope, there is an energy dispersive X-ray spectrometry (hereinafter, referred to as EDX) in which a characteristic X ray generated by emission of an electron beam to the sample is detected by an X-ray detector, and an image is observed and the composition of a minute area which corresponds to an observation visual field is analyzed at the same time.

As the EDX detector, a Si (Li) semiconductor detector [hereinafter, referred to as an SSD detector] has been used. In recent years, a silicon drift detector (hereinafter, referred to as an SDD detector) is newly developed, which is expected for its excellent characteristics.

The SDD detector does not need to use liquid nitrogen for cooling. Therefore, the shape and the size of a detection element can be relatively freely designed. A gap with respect to the sample can be made narrow in accordance with the shape of an objective lens in order to prevent interference. Therefore, an X ray is introduced at a large solid angle compared to the analysis using the SSD detector, and it is possible to realize higher sensitivity and higher energy resolution in the analysis.

In general, the EDX detector is provided with a diaphragm called a collimator immediately before the detection element to shield a scattering X ray from an area other than an incident point of an electron beam on the sample during the analysis.

PTL 1 discloses an EDX detector which is provided with a collimator having a mechanism for preventing a system peak generated by a conflict of the electron beam onto a pole piece from being incident in addition to the scattering X ray in order to detect a desired X ray with a good accuracy in the EDX analysis.

### CITATION LIST

### Patent Literature

PTL 1: Japanese Patent Application Laid-Open No. 2003-161710

### SUMMARY OF INVENTION

### Technical Problem

However, in recent years, the detection element has been increased in its area to simultaneously introduce various characteristic X rays in order to achieve high functionalization and high resolution of the detector. As the area of the detection element is increased, a ratio of the scattering X ray to the characteristic X ray obtained from the incident point of the electron beam of the sample tends to be increased more and more. In particular, in a case where a large SDD detector is used, this tendency becomes noticeable. In the structure disclosed in PTL 1, there is required a distance to some degrees between the sample and the collimator for arrangement. Therefore, there is a limit in angle at which the scattering X ray can be confined. When the ratio of the scattering X ray is increased, a P/B ratio (Peak-to-Background ratio) of an EDX spectrum is reduced, and the analysis on a microelement becomes difficult.

An object of the invention is to provide a sample holder which can efficiently shield the scattering X ray generated in the EDX analysis and realize a high P/B ratio, and a charged particle beam device equipped with the sample holder.

### Solution to Problem

As an aspect to achieve the above object, the present invention provides a sample holder and a device to which the sample holder is applied. The sample holder is inserted into a charged particle beam device, the charged particle beam device including a charged particle source that generates a charged particle beam to be emitted to a sample, and a detector that detects a signal generated from the sample to which the charged particle beam is emitted, and the sample holder includes: a main body that holds the sample; and a sample retaining part that is detachably attached to the main body and is mounted to the main body to fix the sample held in the main body, wherein the sample retaining part includes: a first hole that is provided in a surface facing the charged particle source and allows the charged particle beam to be passed therethrough; and a second hole that is provided in a surface facing the detector and introduces only a specific signal among signals generated from the sample toward the detector.

### Advantageous Effects of Invention

According to the above aspect, since the scattering X ray can be shielded at a position nearer to the sample, the confinable angle is narrowed. Therefore, the scattering X ray generated in the EDX analysis can be efficiently shielded, and a high P/B ratio can be realized.

### BRIEF DESCRIPTION OF DRAWINGS

FIG. 1 is a diagram illustrating an outer appearance of a sample holder and an EDX detector of a charged particle beam device according to a first example.

FIG. 2 is a diagram illustrating a situation where a sample retaining part according to the first example is mounted.

FIG. 3 is a diagram for describing a situation where a scattering X ray generated from a sample is shielded by the sample retaining part according to the first example.

FIGS. 4(a) and 4(b) are diagrams for describing a shielding effect of the sample retaining part according to the first example.

FIG. 5 is a top view illustrating a positional relation between the sample holder according to the first example and a detector.

FIG. 6 is a diagram illustrating a configuration of a transmission electron microscope to which the sample holder according to this embodiment is applied.

FIG. 7 is a diagram illustrating a configuration of a scanning electron microscope to which the sample holder according to this embodiment is applied.

FIG. 8 is a diagram illustrating a configuration of a sample retaining part according to a third example.

FIG. 9 is a diagram illustrating a configuration of a sample hold member of a bulk sample according to a fourth example.

FIG. 10 is a diagram illustrating a configuration of a sample holder according to a fifth example.

FIG. 11 is a graph illustrating a spectrum result in an EDX analysis according to this embodiment.

FIG. 12 is a graph illustrating a relation between a sample inclination angle and a P/B ratio in the EDX analysis according to this embodiment.

FIG. 13 is a flowchart illustrating an example of an optimized procedure of the sample inclination angle in the EDX analysis according to this embodiment.

FIG. 14 is a flowchart illustrating an example of an optimized procedure of each axis of a sample stage in the EDX analysis according to this embodiment.

FIG. 15 is a diagram illustrating a display example of a sample observation condition in the EDX analysis according to this embodiment.

FIG. 16 is a diagram illustrating an example of manufacturing a sample for the EDX analysis according to this embodiment.

FIG. 17 is a diagram illustrating a display example of a sample manufacturing condition for the EDX analysis according to this embodiment.

FIG. 18 is a flowchart illustrating an operation in a case where the EDX analysis is performed using a plurality of electron microscope apparatuses and the sample holder according to this embodiment.

FIG. 19 is a flowchart illustrating an operation in a case where the EDX analysis is performed using a plurality of electron microscopes and EDX detectors according to this embodiment.

FIG. 20 is a perspective view illustrating a moving mechanism of the sample holder according to this embodiment.

FIG. 21 is a diagram illustrating a configuration of a sample retaining part according to a sixth example.

### DESCRIPTION OF EMBODIMENTS

### First Example

In this example, basic embodiments will be described.

[Configurations]

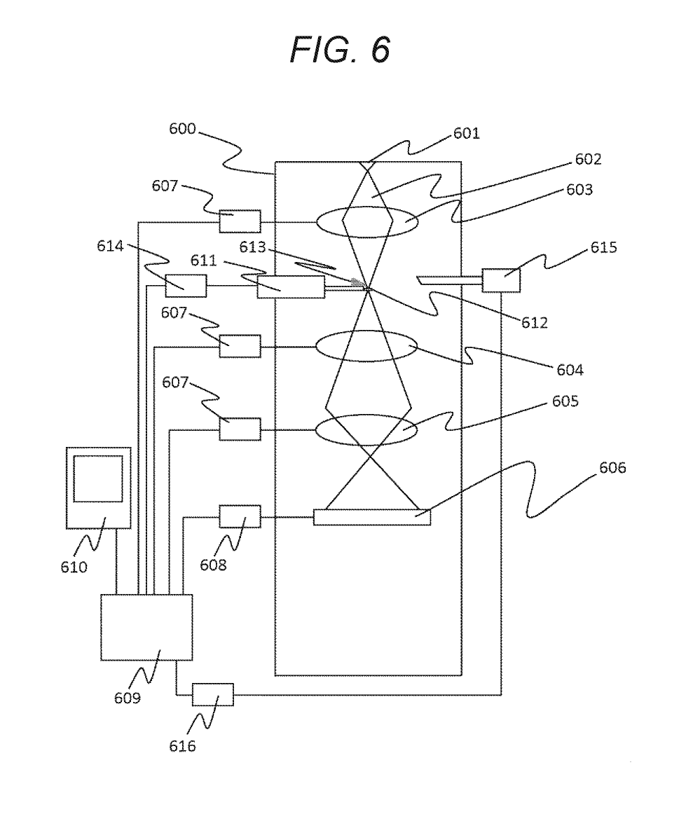

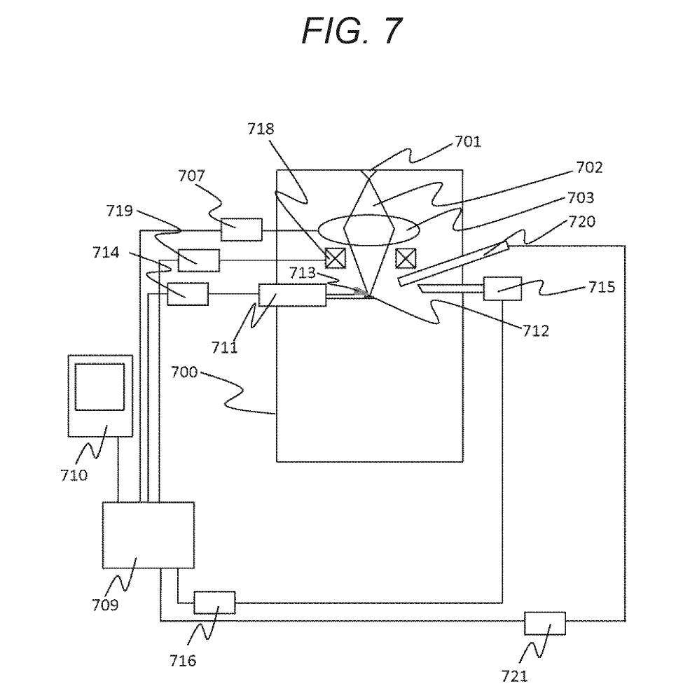

FIG. 6 is a diagram illustrating an exemplary configuration of a transmission electron microscope according to this embodiment. An electron microscope apparatus 600 is mainly configured by an electron gun 601, a convergent lens 603, an objective lens 604, a projection lens 605, a transmitted-electron detector 606, a lens power source 607, a transmitted-electron detector control unit 608, an overall control unit 609, a computer 610, a sample holder body 611, a sample 612, a sample retaining part 613, a sample holder control unit 614, an EDX detector 615, and an EDX detector control unit 616.

The convergent lens 603, the objective lens 604, and the projection lens 605 each are connected to the lens power source 607. The lens power source 607 is connected to the overall control unit 609, and makes communication therewith.

The transmitted-electron detector 606 is connected to the overall control unit 609 through the transmitted-electron detector control unit 608, and makes communication therewith.

The EDX detector 615 is connected to the overall control unit 609 through the EDX detector control unit 616, and makes communication therewith.

The sample holder 611 is connected to the overall control unit 609 through the sample holder control unit 614, and makes communication therewith.

The overall control unit 609 is connected to the computer 610, makes communication therewith. The computer 610 is provided with an output unit having a display unit such as a display, and an input unit such as a mouse and a keyboard.

Herein, the description in the transmission electron microscope of this embodiment has been made about an example in which the lens power source 607, the transmitted-electron detector control unit 608, the sample holder control unit 614, and the EDX detector control unit 616 control the respective portions according to a signal transmitted from the overall control unit 609. These may be configured in one control unit, or other control units for controlling the operations of the respective portions may be included.

An electron beam 602 radiated from the electron gun 601 passes through the convergent lens 603 to be emitted to the sample 612 loaded onto the sample holder body 611. The sample 612 disposed on a sample mesh (not illustrated) is loaded onto the sample holder body 611. The sample retaining part 613 is detachably mounted onto the sample 612.

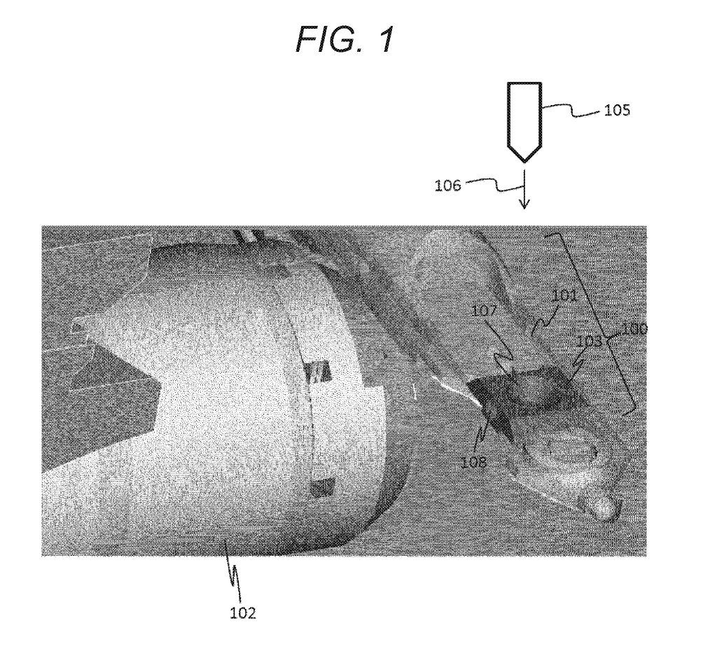

Herein, the detailed configuration of the sample retaining part 613 is omitted in this drawing, but will be described using FIG. 1.

When the electron beam 612 is emitted to the sample 612, the electron beam 602 transmits the sample 612. The transmitted electron beam 612 is imaged by the objective lens 604, and magnified by the projection lens 605.

Thereafter, the electron beam 602 passing through the projection lens 605 is detected by the transmitted-electron detector 606. The transmitted-electron detector 606 sends the detected electrons as a signal to the overall control unit 609 through the transmitted-electron detector control unit 608.

The overall control unit 609 converts the received signal into an image, and performs image processing as needed. Thereafter, the image data is displayed in the display unit of the computer 610. In the transmitted electron image, a position at the time of the EDX analysis can be designated using the converged electron beam.

The sample holder body 611 and the sample holder control unit 614 are provided with a sample micromotion mechanism and an inclination mechanism. The sample can be disposed at a position satisfying an optimal analysis condition by adjusting the operations of the sample micromotion mechanism and the inclination mechanism.

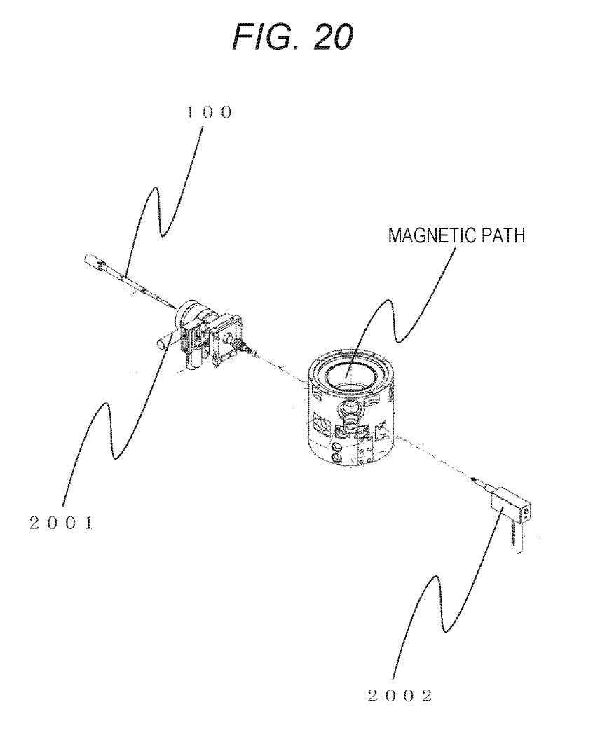

FIG. 20 is a perspective view illustrating a moving mechanism of the sample holder. An X micromotion mechanism 2001 moves a sample holder body 611 of a sample holder 100 in the X direction on the basis of an instruction of the sample holder control unit 614. A Y micromotion mechanism 2002 moves the sample holder body 611 of the sample holder 100 in the Y direction on the basis of an instruction of the sample holder control unit 614.

The EDX detector 615 detects a characteristic X ray generated when the electron beam 602 is emitted to the sample 612, and transmits the characteristic X ray to the EDX detector control unit 616. As the EDX detector control unit 616, an analyzer is used for example, and selects the energy of the received characteristic X ray and then transmits the energy signal to the overall control unit 609. The overall control unit 609 acquires an EDX spectrum on the basis of the received signal, and performs data processing such as an energy correction process and a quantitative calculation process as needed. Thereafter, the EDX spectrum is displayed in the display unit of the computer 610.

FIG. 7 is a diagram illustrating an exemplary configuration of a scanning electron microscope according to this embodiment. An electron microscope apparatus 700 includes an electron gun 701, a convergent lens 703, a lens power source 707, an overall control unit 709, a computer 710, a sample holder body 711, a sample 712, a sample retaining part 713, a sample holder control unit 714, an EDX detector 715, an EDX detector control unit 716, a scanning electrode 718, a scanning power source 719, a secondary-electron/reflected-electron detector 720, and a secondary-electron/reflected-electron detector control unit 721.

The convergent lens 703 is connected to the lens power source 707. The lens power source 707 is connected to the overall control unit 709, and makes communication therewith.

The secondary-electron/reflected-electron detector 720 is connected to the overall control unit 709 through a secondary-electron/transmitted-electron detector control unit 721, and makes communication therewith.

The EDX detector 715 is connected to the overall control unit 709 through the EDX detector control unit 616, and makes communication therewith.

The sample holder 711 is connected to the overall control unit 709 through the sample holder control unit 714, and makes communication therewith.

The scanning electrode 718 is connected to the overall control unit 709 through the scanning power source 719, and makes communication therewith.

The overall control unit 709 is connected to the computer 710, and makes communication therewith. The computer 710 is provided with an output unit having a display unit such as a display, and an input unit such as a mouse and a keyboard.

Herein, the description in the scanning electron microscope of this embodiment has been made about an example in which the lens power source 707, the secondary-electron/reflected-electron detector control unit 721, the sample holder control unit 714, the EDX detector control unit 716, and the scanning power source 719 control the respective portions according to a signal transmitted from the overall control unit 709. These may be configured in one control unit, or other control units for controlling the operations of the respective portions may be included.

An electron beam 702 radiated from the electron gun 701 passes through the convergent lens 703 to be emitted to the sample 712 loaded onto the sample holder body 711. The scanning electrode 718 scans the sample with the electron beam 702. The sample 712 is loaded onto the sample holder body 711, and the sample retaining part 713 is detachably mounted onto the sample 712.

Herein, the detailed configuration of the sample retaining part 713 is omitted in this drawing, but will be described using FIG. 1.

When the electron beam 702 is emitted to the sample 712, secondary electrons and reflected electrons are radiated from the sample 712. The secondary electron and the reflected electron are detected by the secondary-electron/reflected-electron detector 720, and sent as a signal to the secondary-electron/reflected-electron detector control unit 721. Herein, the secondary-electron/reflected-electron detector control unit 721 includes a signal amplification unit, amplifies the acquired signal, and sends the signal to the overall control unit 709.

The overall control unit 709 converts the received signal into an image, and performs image processing as needed. Thereafter, the image data is displayed in the display unit of the computer 710.

Since the secondary electron and the reflected electron radiated when the sample surface is scanned by the scanning electron microscope are used, the displaying image is a scan image. A position at the time of the EDX analysis may be designated using the scan image. In addition, the position at the time of the EDX analysis may be designated such that the transmitted-electron detector is provided in the scanning electron microscope to acquire a scan image of the transmission electron microscope.

The sample holder body 711 and the sample holder control unit 714 are provided with a sample micromotion mechanism and an inclination mechanism which are not illustrated. The sample can be disposed at a position satisfying an optimal analysis condition by adjusting the operations of the sample micromotion mechanism and the inclination mechanism.

Herein, in FIG. 20, the X micromotion mechanism 2001 moves a sample holder body 711 of the sample holder 100 in the X direction on the basis of an instruction of the sample holder control unit 714. The Y micromotion mechanism 2002 moves the sample holder body 711 of the sample holder 100 in the Y direction on the basis of an instruction of the sample holder control unit 714.

The EDX detector 715 detects the characteristic X ray generated when the electron beam 702 is emitted to the sample 712, and transmits the characteristic X ray to the EDX detector control unit 716. For example, an analyzer is used as the EDX detector control unit 716, and selects the energy of the received characteristic X ray and then transmits the energy signal to the overall control unit 709. The overall control unit 709 acquires an EDX spectrum on the basis of the received signal, and performs data processing such as an energy correction process and a quantitative calculation process as needed. Thereafter, the EDX spectrum is displayed in the display unit of the computer 710.

In the transmission electron microscope, a thin film sample is normally observed and analyzed. However, in the scanning electron microscope, a bulk sample other than the thin film is also observed and analyzed. It is possible to improve a P/B ratio even for the bulk sample by providing a collimation function in a member used to hold the sample. An example in a case where the bulk sample is handled will be described in a fourth example below.

[Sample Holder]

FIG. 1 is a diagram illustrating an outer appearance of the sample holder and the EDX detector of a charged particle beam device according to this embodiment.

The sample holder 100 is configured by a sample holder body 101 onto which the sample is loaded, and a sample retaining part 103 which fixes the mounted sample from the upside.

The sample retaining part 103 includes a first hole 107 in a surface facing an electron gun 105, through which an electron beam 106 is incident, and a second hole 108 in the side surface, which introduces only a target characteristic X ray to the EDX detector among the X rays generated from the sample when the electron beam is emitted. In other words, the second hole 108 is an introducing hole for selectively detecting the characteristic X ray which passes through the inside of the sample. Herein, at least one or more second holes 108 are necessary for one EDX detector 102. In a case where a plurality of EDX detectors 102 are provided up and down and right and left of the sample, in the sample retaining part 103, the second holes 108 are provided in correspondence with these detectors. One first hole 107 is sufficient regardless of the number of second holes 108. Since the P/B ratio is considered to be improved when the first hole 107 has a small diameter, the first hole is desirably set as small as possible while considering a field of view that can allow observation.

Further, the sample retaining part 103 described in this drawing can be applied as the sample retaining part 613 in FIG. 6, and as the sample retaining part 713 in FIG. 7.

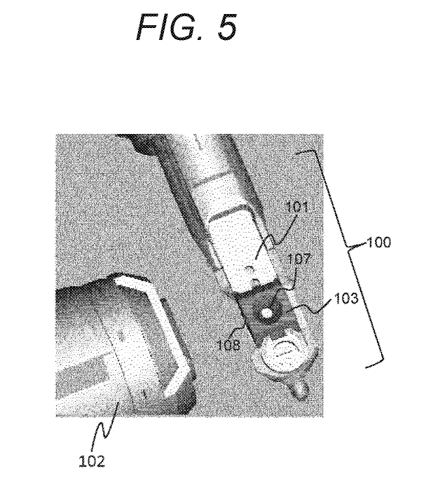

FIG. 5 is a diagram illustrating a positional relation between the sample holder according to this embodiment and the detector when viewed from the upside. As illustrated in this drawing, a detecting surface of the detector 102 is disposed to face the second hole 108 where the sample retaining part 103 provided in the sample holder body 101 is provided. In this drawing, one EDX detector 102 is illustrated. In a case where a plurality of EDX detectors are provided, the second holes 108 are provided at positions similarly facing the detecting surfaces of the added EDX detectors 102.

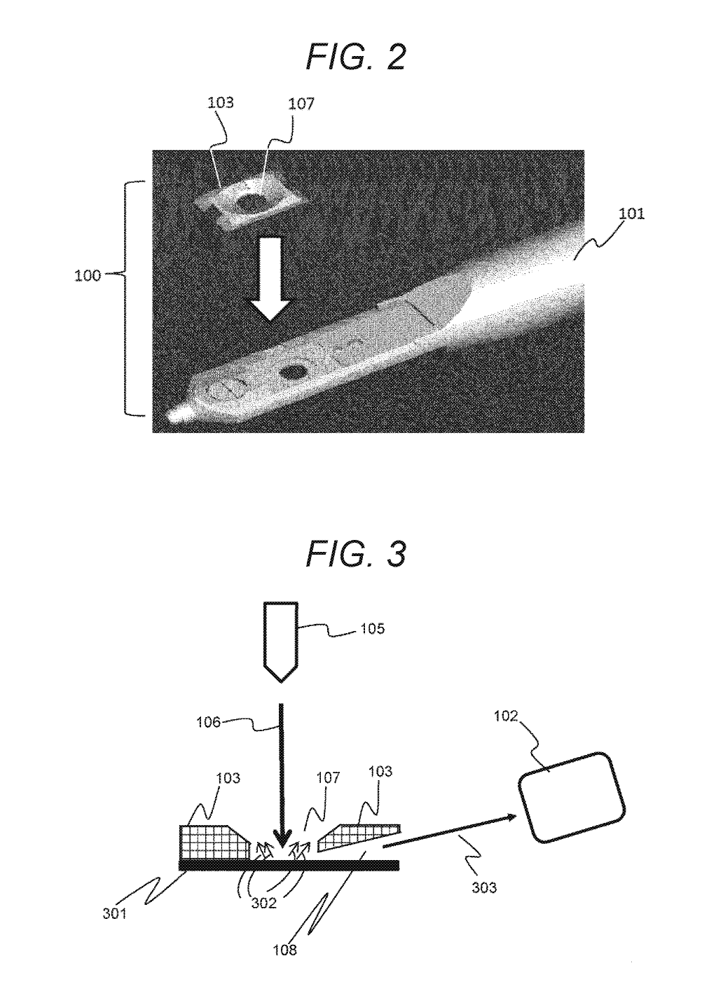

FIG. 2 is a diagram illustrating a situation where the sample retaining part is mounted. The sample retaining part 103 is configured to be detachably attached with respect to a sample holder body 101. When being used, the sample retaining part can be mounted to be fitted into the sample holder body 101 from the upside as illustrated in the drawing.

FIG. 3 is a diagram for describing a situation where a scattering X ray generated from the sample is shielded by the sample retaining part. As illustrated in this drawing, the electron beam 106 radiated from the electron gun 105 passes through the first hole 107 of the sample retaining part 103 and is emitted to a sample 301. Among the X rays 302 generated from the sample 301 in various directions with this emission, only a characteristic X ray 303 passing through the second hole 108 of the sample retaining part 103 is introduced to the EDX detector 102. The other scattering X rays not passing through the second hole 108 are shielded by the sample retaining part 103.

According to the above embodiment, the collimation can be made at a position near to the sample by the configuration of the sample retaining part 103 in the sample holder 100. Therefore, it is also possible to cut the detection of the scattering X ray and the reflected electrons which cannot be shielded by the collimator of the conventional EDX detector 102.

Accordingly, the P/B ratio is improved, and a lower detection limit of a trace element contained in the sample can be improved.

Furthermore, in a case where the collimator is provided in the EDX detector 102, the sample chamber is necessarily opened whenever the collimator is replaced. However, according to the above embodiment, the sample holder 100 is taken out of the charged particle beam device and thus the collimator can be easily replaced. Therefore, a throughput in analysis is also improved. In addition, even in a case where a shielding mechanism of the sample retaining part 103 according to this embodiment is used in combination with the collimator of the EDX detector 102, the scattering X ray near to the sample can be shielded by the former. As a result, a replacement cycle of the latter can be reduced.

Herein, according to the structure of the sample retaining part 103 in the above embodiment, the collimation can be made at a position near to the sample as described above. Therefore, the scattering X ray can be more effectively cut even compared to diaphragm of the projection lens system as well as the collimator of the EDX detector 102.

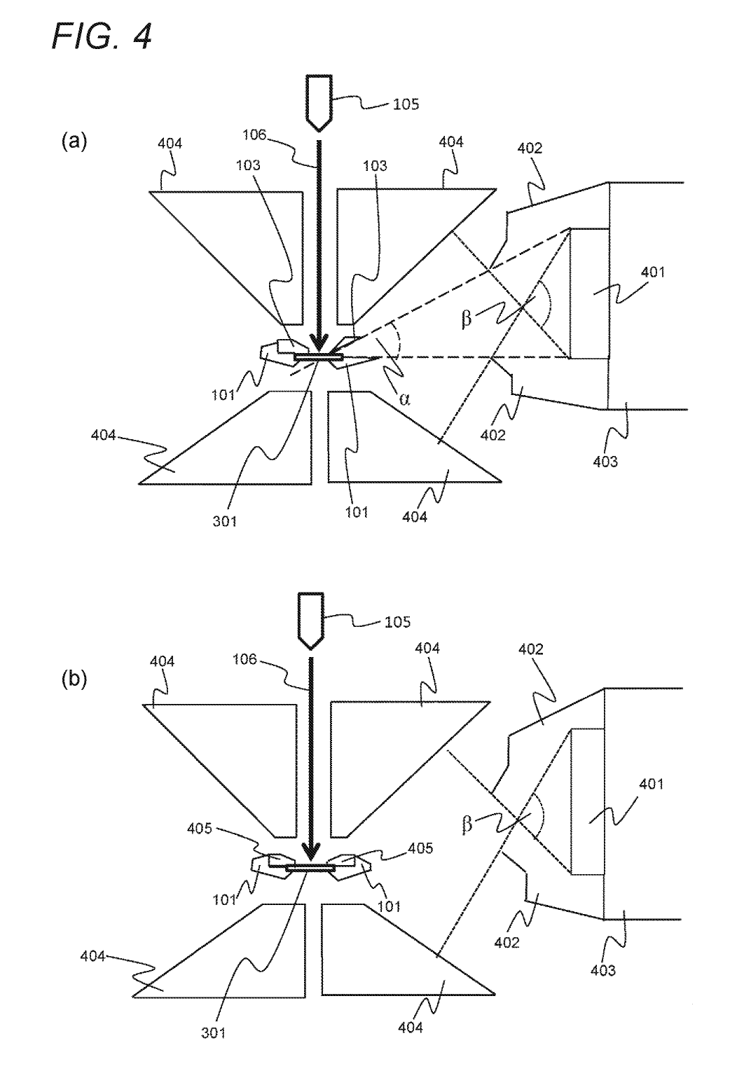

FIGS. 4(a) and 4(b) are diagrams for describing a shielding effect of the sample retaining part according to this embodiment. FIG. 4(a) illustrates a situation where the sample retaining part according to the embodiment of the invention is used (that is, the shielding is made by combining the structures provided in the sample retaining part and the EDX detector. FIG. 4(b) illustrates a situation where the conventional sample retaining part is used (that is, the shielding is made only by the structure provided in the EDX detector).

The sample 301 is disposed on the sample holder body 101, and fixed by the sample retaining part 103 from the upside. When the electron beam 106 radiated from the electron gun 105 is emitted to the sample 301, the X rays are generated from the sample 301 in various direction.

An EDX detector 403 for detecting the X ray includes an EDX detection element 401 and a collimator 402. In a case where the collimation is made only by a combination of the EDX detection element 401 and the collimator 402, an angular range β depicted by a short broken line illustrated in FIGS. 4(a) and 4(b) becomes a detection target area of the characteristic X ray.

Herein, a roll of a conventional sample retaining part 405 illustrated in FIG. 4(b) is simply only to fix the sample. Therefore, there is even no effect of shielding the scattering X ray. On the other hand, in the sample retaining part 103 according to the embodiment of the invention illustrated in FIG. 4(a), there is provided the second hole 108 for introducing only the target characteristic X ray to the EDX detector 403 in addition to the first hole 107 for allowing the electron beam 106 to pass therethrough as described above. An introduction angle of the characteristic X ray formed by the second hole 108 (that is, an angular range α depicted by a long broken line in this drawing) becomes a target detection area of the characteristic X ray. Therefore, the detection range can be made narrow compared to the angular range β in a case where the scattering X ray is shielded only by the configuration of the EDX detector 403.

In this way, in a case where the sample retaining part 103 according to this embodiment is used, not only the scattering X ray and the reflected electron other than the target characteristic X ray generated from the sample 301, but also the unnecessary X ray generated from areas (for example, an objective lens 404, etc.) other than the sample 301 (that is, the scattering X ray which has not been shielded so far) can be prevented from being detected. Therefore, it is possible to achieve a higher collimation effect.

In addition, the sample retaining part 103 according to this embodiment can be replaced in a separate and relatively simple manner without accompanying a large change such as replacement of the EDX detector 403 or a lens in the charged particle beam device. Accordingly, a detection solid angle at the time of the EDX analysis can be adjusted by changing conditions such as a diameter of the second hole 108, a shape, and an inclination angle by replacing the sample retaining part 103. Therefore, even in a case where the main body of the charged particle beam device, the EDX detector, or a combination thereof is changed, it is possible to set the conditions to be matched with the purpose of the analysis at a low cost in a relatively simple manner.

Furthermore, for example, the material itself of the sample retaining part 103 can also be changed according to a composition of the target sample of the EDX analysis. As an example, there are aluminum, carbon, copper, beryllium, and zirconium. The material of the sample retaining part 103 appears as a system peak in the EDX spectrum. Therefore, it is possible to select the sample retaining part 103 made of a material other than those possibly contained in the sample according to the analysis condition. In addition, it is desirable to select an appropriate material such that the energy of a peak of the components in the sample 301 does not approach the energy of the system peak of the sample retaining part 103. For example, in a case where an element of interest is S-Ka (2.31 keV), the sample retaining part 103 made of a material other than the element may be selected in order to avoid the sample retaining part 103 of Mo-La (2.29 keV). Otherwise, the system peak of the EDX spectrum can be suppressed at a minimum level by selecting the material of the sample retaining part 103 to be equal to that of the sample holder body 101 or a sample stage (not illustrated).

In this way, since only the sample retaining part 103 can be simply mounted and replaced, the EDX analysis using the existing charged particle beam device can also be applied.

### Second Embodiment

[EDX Analysis]

In this example, the description will be made using an EDX analysis result on the P/B improvement effect in a case where the sample retaining part 103 according to the first example is applied. FIG. 11 is a graph illustrating an example of resultant spectrums obtained by the EDX analysis acquired from a NiOx thin film sample. In this graph, the horizontal axis represents an energy range, and the vertical axis represents a peak intensity (count number).

The P/B ratio of the EDX spectrum is calculated using Fiori Equations (1) to (3) for example.

P/B=50×P/B₅₀₀ Equation (1)

P=P₁−B₅₀₀ Equation (2)

B₅₀₀=(B1+B2)/2 Equation (3)
P/B ratio (Peak to Background Ratio): Ratio of peak to background
P₁ and P₂ (Peak): Integrated values of the count numbers in 500 eV energy width with the center of a Ni-K_{α} peak and a Ni-K_{β} peak
B₁ and B₂ (Background): Integrated values of the count numbers in the energy widths B₁ and B₂ of FIG. 11
B₅₀₀: An average value of B₁ and B₂

Herein, the Ni-K_{α} peak indicates the characteristic X ray detected when the electrons introduced to the sample move L shell → K shell of Ni. The Ni-K_{b} peak indicates the characteristic X ray detected when the electrons introduced to the sample move M shell → K shell of Ni.

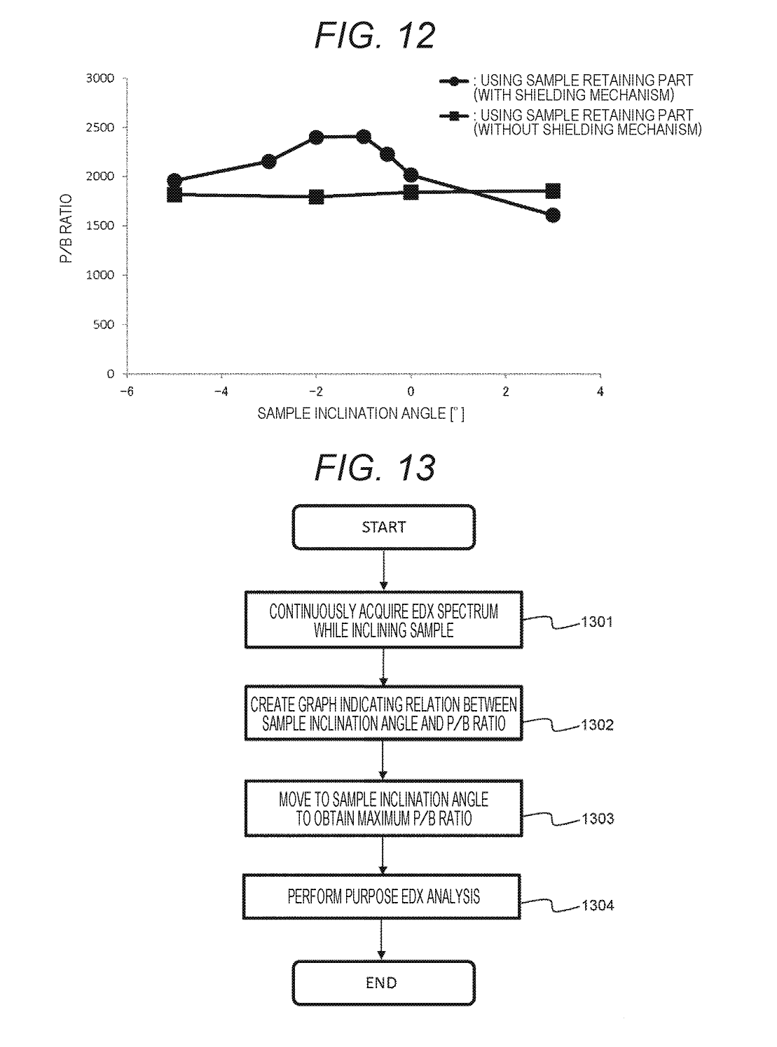

Next, FIG. 12 is a graph illustrating a relation between a sample inclination angle and the P/B ratio in the EDX analysis to which the sample retaining part 103 according to this embodiment is applied. This graph shows a relation between the P/B ratio obtained by the above method and the inclination angle of the sample after the EDX analysis is performed to acquire the EDX spectrum in a case where the sample retaining part 103 having the shielding mechanism according to the first example is used, and the (conventional) sample retaining part having no shielding mechanism is used for the same sample. In this graph, the horizontal axis represents the inclination angle of the sample, and the vertical axis represents the P/B ratio.

In the sample retaining part 103 having the shielding mechanism, the P/B ratio is maximized by optimizing the inclination angle of the sample. On the other hand, in the sample retaining part 405 having no shielding mechanism, it can be seen that an influence of the change in the sample inclination angle to the P/B ratio is less. In addition, in the sample retaining part 103 having the shielding mechanism, it can be seen that the P/B ratio is improved by about 30% in the maximum area compared to the sample retaining part 405 having no shielding mechanism.

From this result, it is confirmed that the P/B ratio can be significantly improved only by applying the sample retaining part 103 according to the first example without changing the configuration of the sample holder.

FIG. 13 is a flowchart illustrating an example of a procedure of adjusting the sample inclination angle to set an optimal EDX analysis condition. First, the sample retaining part 103 according to the first example is mounted in the sample holder body 101 loaded with the sample. The EDX spectrum is continuously acquired by irradiating the sample with the electron beam 106 while inclining the sample (S1301). Next, the P/B ratio of the target element in the sample is obtained from the acquired EDX spectrum. A graph indicating a relation with respect to the sample inclination angle is created (S1302). Then, the sample is moved again to be the sample inclination angle showing a maximum value on the basis of the created graph (S1303). The EDX analysis is performed for the purpose of analyzing point, line, face, quantity, and phase (S1304). When an optimal analysis condition is determined, a sample having noticeable contamination or electron beam damage is subjected to the purpose EDX analysis after an optimal sample inclination angle is obtained near to a desired analysis area. A step in the inclination angle of the sample depends on the accuracy of a sample stage, but the analysis is desirably performed at a minimum step of the sample stage. However, in this case, the measurement time becomes long. Therefore, the P/B ratio may be roughly ascertained by continuously inclining the sample while acquiring the EDX spectrum at a several-seconds interval in a predetermined analysis time. Thereafter, in a high angular range of the P/B ratio, accurate maximum coordinates can also be obtained by remeasuring the EDX spectrum at a finer inclination angle interval in a longer acquisition time.

The above description has been made about the relation between the inclination of the sample and the P/B ratio. However, the P/B ratio is changed by changing various parameters such as a sample shape, and a horizontal axis (X), a vertical axis (Y), and a height axis (Z) of the stage coordinates. Therefore, the position of the sample retaining part 103 may be finely adjusted using a micromotion mechanism of the sample stage as needed.

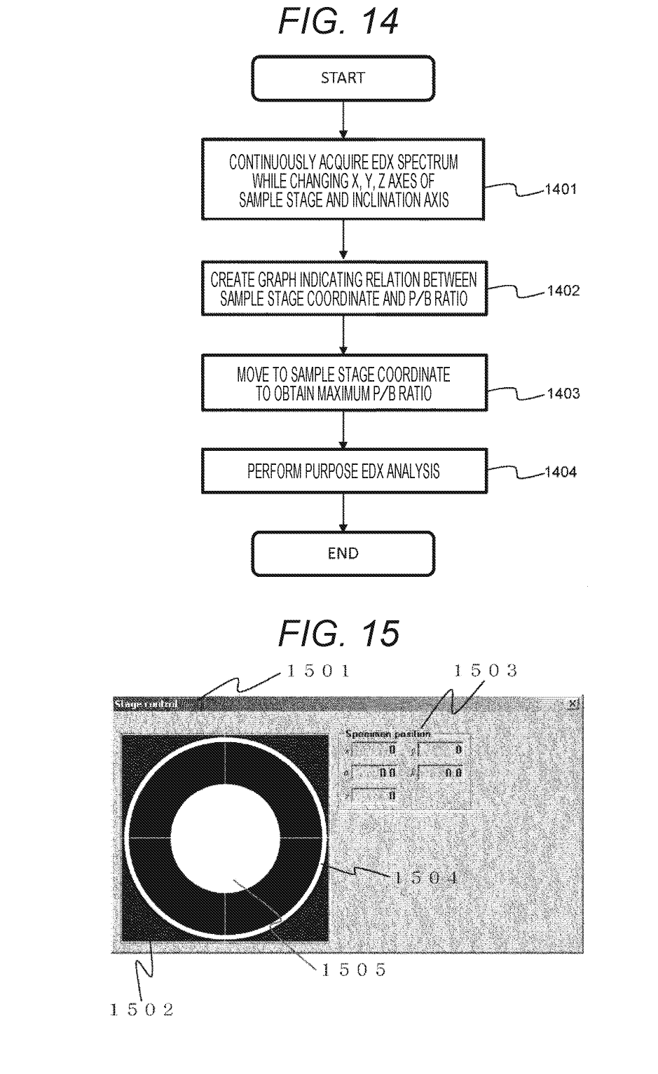

FIG. 14 is a flowchart illustrating an example of a procedure of adjusting the respective axes of the sample stage for setting the optimal EDX analysis condition.

First, the sample retaining part 103 according to the first example is mounted in the sample holder body 101 onto which the sample is loaded. The electron beam 106 is emitted to the sample while changing the X, Y, and Z axes and the inclination axis of the sample stage and while inclining the sample so as to acquire the continuous EDX spectrum (S1401). Next, the P/B ratio of the target element in the sample is obtained from the obtained EDX spectrum. A graph indicating a relation with respect to the sample stage coordinates is created (S1402). Then, the sample is moved again to the sample stage coordinates showing a maximum value on the basis of the created graph (S1403). The EDX analysis is performed for the purpose of analyzing point, line, face, quantity, and phase (S1404).

Similarly to the above example illustrated in FIG. 13, when an optimal analysis condition is determined, a sample having noticeable contamination or electron beam damage is subjected to the purpose EDX analysis after the optimal sample stage coordinates are obtained near to a desired analysis area. In addition, an interval for changing the sample stage coordinates depends on the accuracy of the sample stage, but the analysis is desirably performed at a minimum step of the sample stage. However, in this case, the measurement time becomes long. Therefore, the P/B ratio may be roughly ascertained by continuously moving the sample stage while acquiring the EDX spectrum at a several-seconds interval in a predetermined analysis time. Thereafter, in a high angular range of the P/B ratio, accurate maximum coordinates can also be obtained by remeasuring the EDX spectrum at a finer coordinate interval of the sample stage in a longer acquisition time.

FIG. 15 illustrates an example of a stage control (sample stage coordinate control) window of control software for controlling the charged particle beam device of an electron microscope. The stage control window 1501 is configured by a moving range display portion 1502 which displays a current position, a stored position, a trace of the sample, and a position information display portion 1503 which displays position information (specimen position) of the current position. The moving range display portion 1502 is configured to display an observable range 1504 which is changed according to a combination between the sample holder body 101 and the sample retaining part 103. In addition, a coordinate range 1505 which is suitable to the EDX analysis can also be displayed in the observable range 1504.

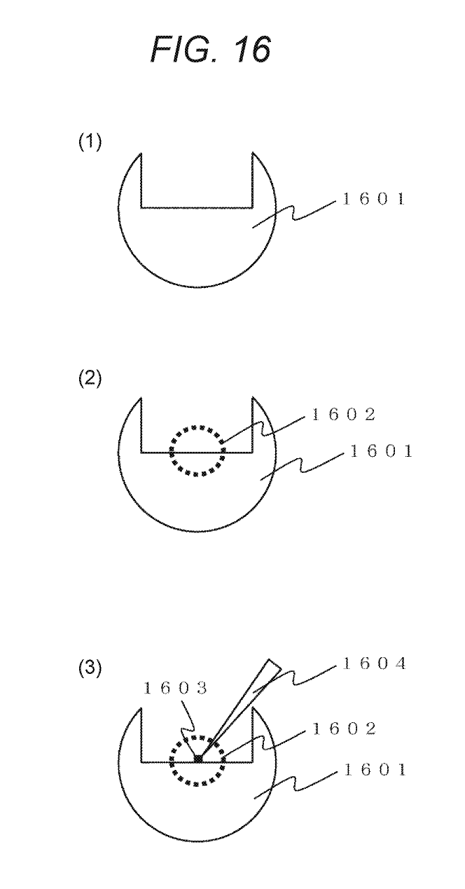

FIG. 16 is a diagram illustrating an example of a sample creating method using an FIB apparatus (Focused Ion Beam; hereinafter, simply referred to as FIB) for acquiring a good EDX spectrum. With the use of a microsampling of the FIB, in a method of fixing a sample stage 1601 as illustrated in FIG. 16(1), a sample 1603 is fixed into, for example, a coordinate range 1602 covering the center of the sample stage and the surroundings thereof which is suitable to the EDX analysis as depicted by a dotted circle in FIG. 16(2). When the sample 1603 is fixed, the sample 1603 is carried to the sample stage 1601 by a manipulator 1604 as illustrated in FIG. 16(3) and fixed thereto.

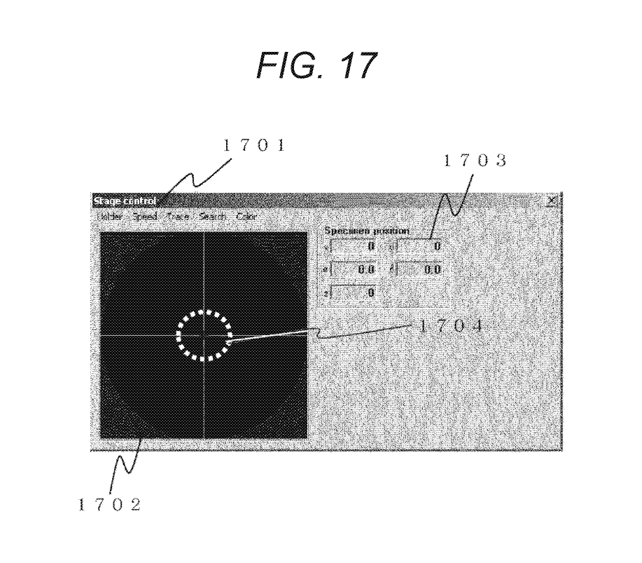

When the manipulator is carried together into the charged particle beam device such as the electron microscope, the FIB, and an ion microscope to manufacture the sample or carry the sample, a coordinate range 1704 of a sample fixing position suitable to the EDX analysis is displayed in the moving range display portion 1702 of a stage control (sample stage coordinate control) window 1701 of the control software as illustrated in FIG. 17. The window 1701 includes the position information display portion 1703 which displays the position information of the current position. On the other hand, when a bulk sample is subjected to cross section processing or thin film processing without using the manipulator, the processing position may be input in the coordinate range 1704 suitable to the EDX analysis.

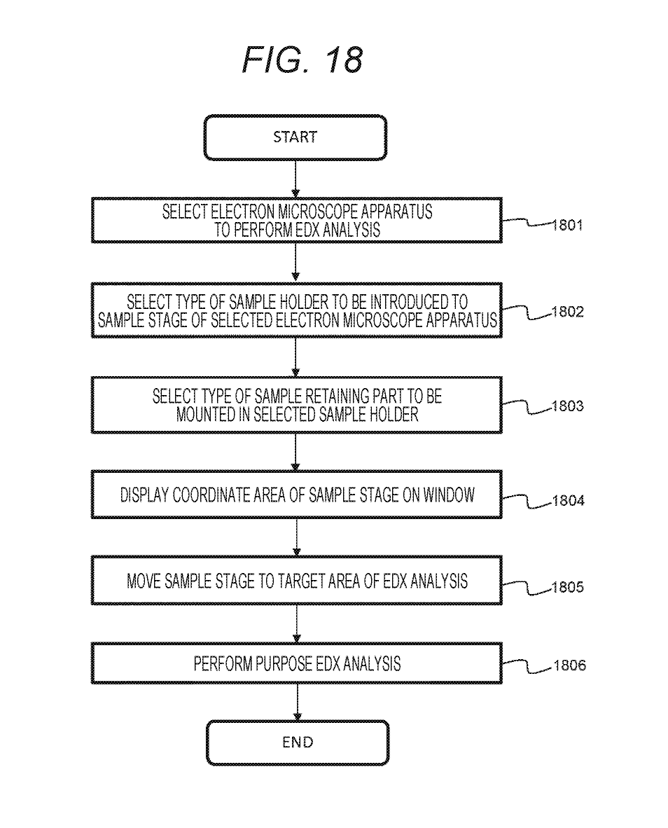

FIG. 18 is a flowchart illustrating an operational sequence in a case where a plurality of electron microscope apparatuses or a plurality of sample holders are selected and replaced to perform the EDX analysis. First, an electron microscope apparatus to perform the EDX analysis is selected (S1801). Next, a type of the sample holder 100 to be introduced to the sample stage of the selected electron microscope apparatus is selected (S1802). Then, a type of the sample retaining part 103 to be mounted in the sample holder body 101 of the selected sample holder 100 is selected (S1803). Herein, the selection of the sample holder 100 and the sample retaining part 103 can be made by instructing the control unit through the above sample stage control software. Next, the coordinate area of the sample stage is displayed on the window (S1804). The sample stage is moved to the target area of the EDX analysis (S1805). Herein, the area suitable to the analysis in the target area of the EDX analysis may be obtained by an experiment using a reference sample in advance, or may be obtained using a simulation. After the sample stage is moved, the purpose EDX analysis is performed (S1806).

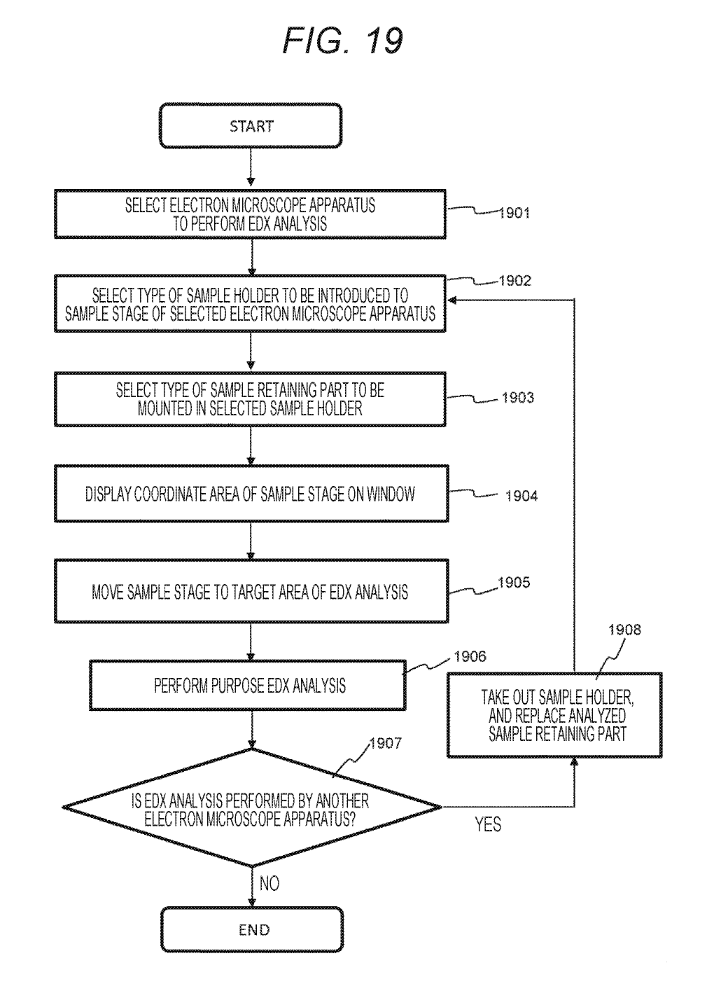

FIG. 19 is a flowchart illustrating an operational sequence in a case where the EDX analysis is performed by a plurality of electron microscope apparatuses or EDX detectors using the same sample and the same sample holder. First, an electron microscope apparatus to perform the EDX analysis is selected (S1901). Next, a type of the sample holder 100 to be introduced to the sample stage of the selected electron microscope apparatus is selected (S1902). Then, a type of the sample retaining part 103 to be mounted in the sample holder body 101 of the selected sample holder 100 is selected (S1903). Herein, the selection of the sample holder 100 and the sample retaining part 103 can be made by instructing the control unit through the above sample stage control software. Next, the coordinate area of the sample stage is displayed on the window (S1904). The sample stage is moved to the target area of the EDX analysis (S1905). After the sample stage is moved, the purpose EDX analysis is performed (S1906). Thereafter, it is determined whether the EDX analysis is performed by another electron microscope apparatus (S1907). In a case where the analysis is not performed, the procedure is ended. In a case where the analysis is performed, the sample holder 100 is taken out of the analyzed electron microscope apparatus. The analyzed sample retaining part 103 is replaced with another one for the electron microscope to be used for the next EDX analysis (S1908). Thereafter, the sample holder 100 is inserted into the electron microscope apparatus which performs the next EDX analysis. Similarly, the EDX analysis is repeatedly performed.

In this sequence, a stage coordinate area suitable to the EDX analysis depends on various conditions such as the shape of the objective lens of the electron microscope apparatus and the element of the EDX detector. Therefore, the stage coordinate area may be obtained by experiment on respective combinations using the reference sample, or may be obtained through a simulation. In this way, a plurality of types of the sample retaining parts 103 may be prepared according to the combinations of the electron microscope apparatus and the EDX detector. Therefore, even when the analysis is performed by a different apparatus, it is possible to perform an optimal EDX analysis only by simply replacing the sample retaining part 103.

In addition, when the sample is manufactured by the FIB for example and the observation or the analysis is performed by the electron microscope as well as the EDX analysis, the sample retaining parts 103 having various shapes and materials are prepared for the replacement according to its purpose. Therefore, it is possible to simply optimize the conditions according to the respective processes such as confining a diameter of the observation visual field or an inclination of the sample, and confining a range of incident direction of electron/ion beam with respect to the sample.

The EDX detector described in this example can be applied to any device other than the SDD, and it can be effectively applied to an Si (Li) detector for example. It is possible to acquire an optimal EDX spectrum by changing the shape of the sample retaining part 103 according to the detection solid angle of the EDX detector.

In addition, while the above embodiment has been described using an application of the X-ray analysis, it can be expected an application of analyzing the light radiated when the electron beam is emitted to the sample in a vacuum state such as a cathodoluminescence (CL).

### Third Example

In the above example, the description has been made about the configuration that the sample retaining part is provided with the shielding mechanism such as the scattering X ray. In this example, the description will be made about a configuration of the sample retaining part equipped with a structure for suppressing the emission of an unnecessary electron beam with respect to the sample in addition to the above shielding mechanism.

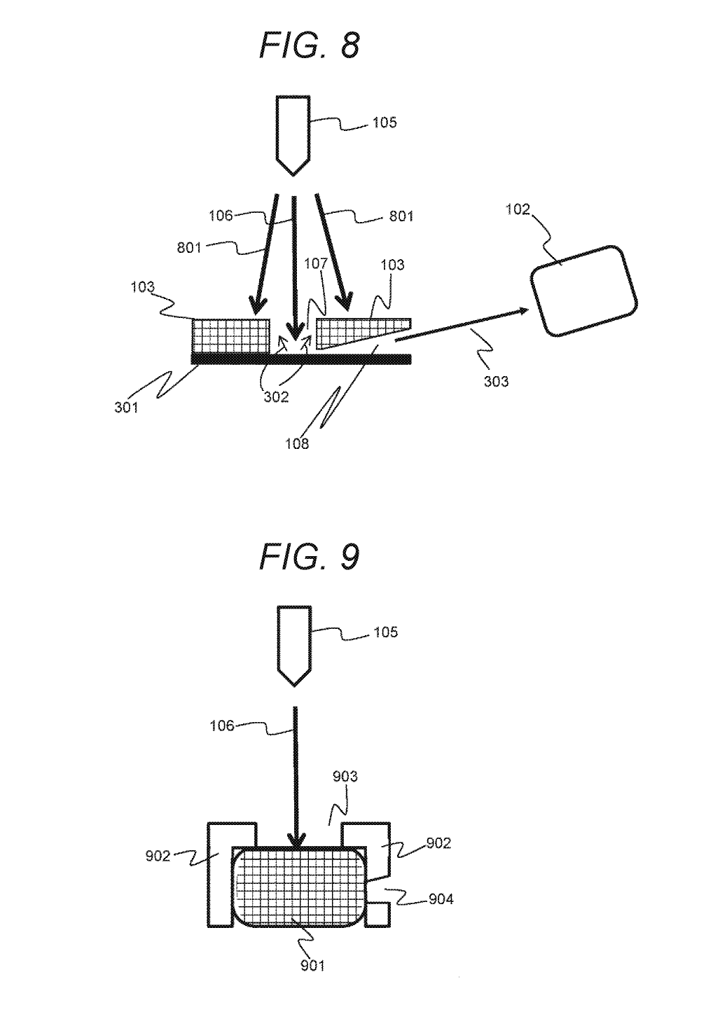

FIG. 8 is a diagram illustrating the configuration of the sample retaining part according to a third example. A different point in the configuration from the first example is that there is no inclination in the first hole 107 of the sample retaining part 103, and the diameter is made small. With such a configuration, the unnecessary electron beam 801 is blocked by the sample retaining part 103 as illustrated in this drawing, and is not emitted to the sample 301. Since the emission of the unnecessary electron beam 801 can be confined within a position nearer to the sample, it is possible to achieve an effect as a diaphragm of an emission lens system simultaneously in addition to the shielding effect described above.

### Fourth Example

In this example, the description will be made about a modification in a case where the bulk sample is handled. FIG. 9 is a diagram illustrating a configuration of a sample hold member according to the fourth example. As illustrated in this drawing, a bulk sample 901 is fixed by a sample hold member 902 in place of the sample retaining part 103 in the above example. The sample hold member 902 is configured to cover the entire bulk sample 901. A first hole 903 for allowing the electron beam 106 to be incident thereon is provided in the surface facing the electron gun 105. A second hole 904 for shielding the scattering X ray generated from the bulk sample 901 when the electron beam is emitted is provided in the side surface. The second hole 904 is an introducing hole for selectively detecting the characteristic X ray generated from a bulk sample 901.

### Fifth Example

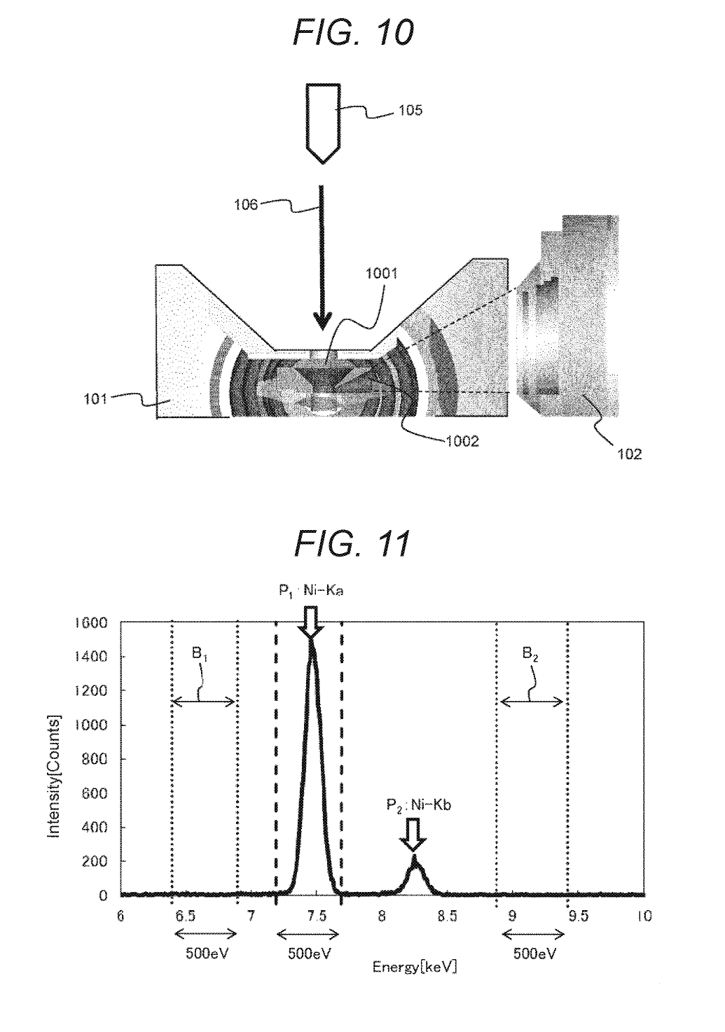

In the above example, the description has been made mainly about the configuration that the shielding mechanism such as the scattering X ray is provided as a member for fixing the sample. In this example, the description will be made about a configuration that the mechanism is provided in the sample holder body. FIG. 10 is a diagram illustrating the configuration of the sample holder body 101 which is provided with the shielding mechanism. The sample holder body 101 includes a first hole 1001 for allowing the electron beam 106 to be incident in the surface facing the electron gun 105, and a second hole 1002 in the side surface in order to shield the scattering X ray generated from the sample when the electron beam is emitted. In other words, the second hole 1002 is an introducing hole through which the EDX detector 102 selectively detects the characteristic X ray passing through the inside of the sample.

### Sixth Example

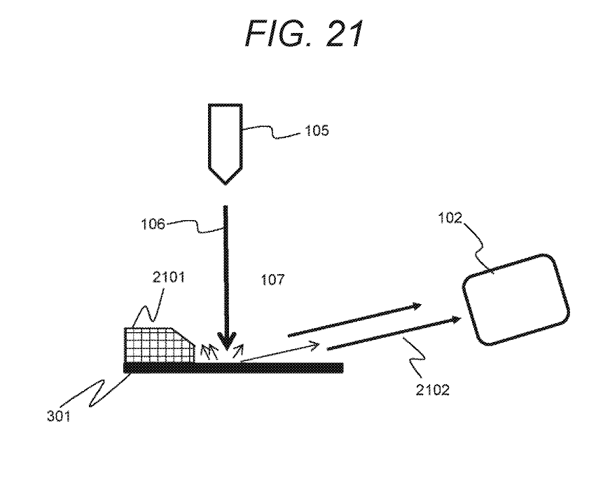

By the way, a higher throughput is required in the EDX analysis in some cases. In this example, the description will be made about a sample retaining part 2101 configured such that a part of the sample 301 is fixed in place of the sample retaining part 103 equipped with the shielding mechanism in the above embodiment. FIG. 21 is a diagram illustrating the configuration of the sample retaining part according to this example. According to the configuration illustrated in this drawing, only a part of the sample 301 is fixed by the sample retaining part 2101. In other words, a part of the EDX detector 102 is removed such that the X ray 2102 generated from the sample 301 is not cut by the sample retaining part 2101. Therefore, the X ray 2102 generated by emitting the electron beam 106 radiated from the electron gun 105 to the sample 301 is not shielded by the sample retaining part 2101, but progresses toward the EDX detector 102. The configuration of the sample retaining part for realizing a higher throughput will be described.

According to the above embodiment, the P/B ratio becomes low compared to the EDX analysis using the sample retaining part 103 described in the first example, but improvement in the CPS (Counts per second) is expected. Therefore, it is possible to analyze a rough composition of the analysis target sample at a high speed. In addition, since an influence of the sample inclination on the EDX spectrum is less, it is effectively applied to a crystalline sample which is necessarily matched with the inclination of the incident axis of the electron beam.

Further, the invention is not limited to the above examples, and includes various modifications. For example, the above examples have been described in detail for easy understanding on the invention. The invention is not necessarily limited to a configuration provided with all the described components. In addition, some of the configurations of a certain example may be replaced with those of the other examples, and the configurations of the other examples may be added to those of the subject example. In addition, some of the configurations of each example may be added, omitted, replaced with other configurations.

In addition, some or all of the respective configurations, functions, processing units, and processing means may be realized in hardware by an integrated circuit for example. In addition, the respective configurations and functions may be realized in software such that the processor analyzes programs for realizing the respective functions and executes the programs. The information such as the programs, tables, and files for realizing the respective functions may be provided in a recording device such as a memory, a hard disk, and an SSD, or a recoding medium such as an IC card, an SD card, and a DVD.

In addition, the control lines and the information lines considered as necessary are illustrated, and it does not mean that all the control lines and the information lines necessary in manufacturing are illustrated. Almost all the configurations are actually connected to each other.

### REFERENCE SIGNS LIST

100 sample holder
101 sample holder body
102 EDX detector
103 sample retaining part
105 electron gun
106 electron beam
107 first hole (of sample retaining part)
108 second hole (of sample retaining part)
301 sample
302 X ray generated from sample
303 characteristic X ray
401 EDX detector
402 collimator (in EDX detector)
403 EDX detector
404 objective lens
405 conventional sample retaining part
600 electron microscope apparatus
601 electron gun
602 electron beam
603 convergent lens
604 objective lens
605 projection lens
606 transmitted-electron detector
607 lens power source
608 transmitted-electron detector control unit
609 overall control unit
610 computer
611 sample holder body
612 sample
613 sample retaining part
614 sample holder control unit
615 EDX detector
616 EDX detector control unit
700 electron microscope apparatus
701 electron gun
702 electron beam
703 convergent lens
707 lens power source
709 overall control unit
710 computer
711 sample holder body
712 sample
713 sample retaining part
714 sample holder control unit
715 EDX detector
716 EDX detector control unit
718 scanning electrode
719 scanning power source
720 secondary-electron/reflected-electron detector
721 secondary-electron/reflected-electron detector control unit
801 unnecessary electron beam
901 bulk sample
902 sample hold member
903 first hole (of sample hold member)
904 second hole (of sample hold member)
1001 first hole (of sample holder)
1002 second hole (of sample holder)
1501 stage control window
1502 moving range display portion
1503 position information display portion
1504 observable range
1505 coordinate range suitable to EDX analysis
1601 sample stage
1602 coordinate range suitable to EDX analysis
1603 sample
1604 manipulator
1701 stage control window
1702 moving range display portion
1703 position information display portion
1704 coordinate range suitable to EDX analysis
2001 X micromotion mechanism
2002 Y micromotion mechanism
2101 sample retaining part
2102 X ray

1. A sample holder that is inserted into a charged particle beam device, the charged particle beam device including a charged particle source that generates a charged particle beam to be emitted to a sample, and a detector that detects a signal generated from the sample to which the charged particle beam is emitted, the sample holder comprising:
a main body that holds the sample; and
a sample retaining part that is detachably attached to the main body and is mounted to the main body to fix the sample held in the main body,
wherein the sample retaining part includes:
a first hole that is provided in a surface facing the charged particle source and allows the charged particle beam to be passed therethrough; and
a second hole that is provided in a surface facing the detector and introduces only a specific signal among signals generated from the sample toward the detector.

2. The sample holder according to claim 1,
wherein the second hole is formed to introduce only a signal progressing in a specific angular range among signals generated from the sample toward the detector.

3. The sample holder according to claim 1,
wherein the second hole is formed such that a diameter becomes smaller as it goes near to the sample disposed in the main body from the surface facing the detector.

4. The sample holder according to claim 1,
wherein the second hole is formed to make a down gradient as it goes near to the sample disposed in the main body from the surface facing the detector.

5. The sample holder according to claim 1,
wherein the detector is an energy dispersive X-ray detector that detects an X ray generated from the sample to which the charged particle beam is emitted.

6. The sample holder according to claim 5,
wherein the detector is a silicon drift detector.

7. The sample holder according to claim 1,
wherein the sample retaining part includes a plurality of the second holes.

8. A charged particle beam device comprising:
a sample holder that holds a sample;
a charged particle source that generates a charged particle beam to be emitted to the sample; and
a detector that detects a signal generated from the sample to which the charged particle beam is emitted,
wherein the sample holder includes:
a main body in which the sample is disposed; and
a sample retaining part that is detachably attached to the main body and mounted to the main body to fix the sample disposed in the main body, and
wherein the sample retaining part includes:
a first hole that is provided in a surface facing the charged particle source and allows the charged particle beam to be passed therethrough; and
a second hole that is provided in a surface facing the detector and introduces only a specific signal among signals generated from the sample toward the detector.

9. The charged particle beam device according to claim 8,
wherein the second hole is formed to introduce only a signal progressing in a specific angular range among signals generated from the sample toward the detector.

10. The charged particle beam device according to claim 8,
wherein the second hole is formed such that a diameter becomes smaller as it goes near to the sample disposed in the main body from the surface facing the detector.

11. The charged particle beam device according to claim 8,
wherein the second hole is formed to make a down gradient as it goes near to the sample disposed in the main body from the surface facing the detector.

12. The charged particle beam device according to claim 11,
wherein the detector is an EDX detector that detects an X ray generated from the sample to which the charged particle beam is emitted.

13. The charged particle beam device according to claim 12,
wherein the detector is a silicon drift detector.

14. The charged particle beam device according to claim 8,
wherein the sample retaining part includes a plurality of the second holes.

15. The charged particle beam device according to claim 8, further comprising:
a sample holder inclination unit that inclines the sample holder; and
a control unit that controls the sample holder inclination unit,
wherein the control unit controls an operation of the sample holder inclination unit to make an inclination angle at which a peak/background ratio of a signal detected by the detector is maximized.
